(19) United States
(12) Patent Application Publication
(10) Pub. No.: US 2006/0133471 A1
(43) Pub. Date: Jun. 22, 2006

(54) Coefficient update circuit, adaptive equalizer including the coefficient update circuit, and coefficient update method of the adaptive equalizer

(75) Inventor: Hoon-Jae Ki, Anyang-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/305,370

(22) Filed: Dec. 16, 2005

(30) Foreign Application Priority Data
Dec. 20, 2004 (KR) 10-2004-0108821

(51) Int. Cl. H03K 5/159

(52) U.S. Cl. 375/232

(57) ABSTRACT

A coefficient update circuit, an adaptive equalizer including the coefficient update circuit, and a coefficient update method of the adaptive equalizer are provided. The coefficient circuit includes: an error level detector, which detects the level of an error signal that is a difference between the level of an output signal of the adaptive equalizer and a desired signal level; and a plurality of coefficient generators, which generate current filter coefficient values by adding update values designated by the level of the error signal and the levels of delayed input signals to previous filter coefficient values, the delayed input signals being generated by delaying an input signal of the adaptive equalizer for a predetermined amount of time. The generated current filter coefficient values are provided to a filter included in the adaptive equalizer. The coefficient update circuit can achieve a high coefficient update speed and can appropriately update filter coefficients even when the levels of the delayed input signals and the error signal dramatically change.

This application claims the benefit of Korean Patent Application No. 10-2004-0108821, filed on Dec. 20, 2004, in the Korean Intellectual Property Office, the disclosure of which is incorporated herein in its entirety by reference.

### BACKGROUND OF THE INVENTION

1. Field of the Invention

The present invention relates to an adaptive equalizer, and more particularly, to a coefficient update circuit that uses a level detection least mean square (LD LMS) algorithm, an adaptive equalizer including the coefficient update circuit, and a coefficient update method of the adaptive equalizer.

2. Description of the Related Art

Adaptive equalizers (or channel adaptive equalizers) are signal processing devices used for compensating for the distortion of signals that are transmitted/received by a transmission/reception system of a communication system or a storage media. In general, an adaptive equalizer updates a filter coefficient (or a tap coefficient) of a finite impulse response (FIR) filter installed therein using a least mean square (LMS) algorithm. An LMS algorithm is used for equalizing the level of a signal output from an adaptive equalizer to a desired signal level by continuously adjusting a filter coefficient in such a manner that minimizes a mean square error between the level of the output signal of the adaptive equalizer and the desired signal level.

FIG. 1 is a block diagram of a conventional adaptive equalizer 100 having a conventional coefficient update circuit 200 that uses an LMS algorithm. Referring to FIG. 1, the conventional adaptive equalizer 100 includes a delay circuit 110, a coefficient multiplier circuit 120, an adder circuit 130, an error generation circuit 140, and the conventional coefficient update circuit 200.

The delay circuit 110, the coefficient multiplier circuit 120, and the adder circuit 130 constitute an FIR filter having m taps. The FIR filter compensates for distortion of an input signal X(k) transmitted thereto via a channel based on filter coefficients C1(k) through Cm(k) output from the coefficient update circuit 200 and outputs an output signal Y(k) having a desired signal level as the compensation result.

The delay circuit 110 generates a plurality of delayed input signals X(k−1), . . . , X(k−m), . . . , X(k−n) by delaying the input signal X(k) for a predetermined amount of time (for example, a multiple of a cycle of a clock signal). Here, m is a natural number greater than 1, and n is a natural number larger than m and satisfies the following equation: n=2m. The input signal X(k) may be a 6-bit digital radio frequency (RF) signal output from an analog-to-digital converter (ADC) of a system for reproducing data from an optical disc. The RF signal is a signal read out or output from a compact disc (CD) or a digital versatile disc (DVD).

The coefficient multiplier circuit 120 multiplies the delayed input signals X(k−1) through X(k−m) with their respective coefficients C1(k) through Cm(k) output from the coefficient update circuit 200 and outputs the multiplication results to the adder circuit 130.

The adder circuit 130 generates the output signal Y(k) by adding up the multiplication results output from the coefficient multiplier circuit 120. For example, the output signal Y(k) may be a 6-bit digital signal input to a viterbi decoder of the system for reproducing data from the optical disc.

The error generation circuit 140 calculates a difference between the level of the output signal Y(k) and a desired signal level (for example, an input signal level required by the viterbi decoder) and generates an error signal E(k) as the calculation result. For example, the error signal E(k) may be a 6-bit digital signal.

The coefficient update circuit 200 utilizes an LMS algorithm. The coefficient update circuit 200 receives the delayed input signals X(k−m−1) through X(k−n), the error signal E(k), and an update size μ and updates the filter coefficients C1(k) through Cm(k) using them. The update size μ is a step size or an adaptation constant used for controlling the convergence rates of filter coefficients and may be input from a controller external to the conventional adaptive equalizer 100.

FIG. 2 is a circuit diagram of an example of the conventional coefficient update circuit 200 of FIG. 1 that uses the LMS algorithm. Referring to FIG. 2, the LMS algorithm used by the coefficient update circuit 200 can be expressed using Equation (1):
C(t+1)=C(t)+μE(t)X(t) (1)

where C(t+1) is a current value of a filter coefficient, C(t) is a previous value of the filter coefficient, μ is an update size, E(t) is an error signal generated at a predetermined moment t of time, and X(t) is a delayed input signal generated at the predetermined moment t of time, i.e., one of X(k−m−1), X(k−m−2), . . . , and X(k−n) of FIG. 1.

Referring to FIG. 2, the coefficient update circuit 200 includes a multiplier 210 and a plurality of coefficient generators, i.e., first through m-th coefficient generators 221 through 22m.

The multiplier 210 multiplies the error signal E(k) with the update size μ and provides the multiplication result μE(k) to the first through m-th coefficient generators 221 through 22m.

The first coefficient generator 221 includes a multiplier 231, an adder 232, and a delay element (D) 233. The first coefficient generator 221 generates a current filter coefficient value C1(k+1) by multiplying μE(k) with the delayed input signal X(k−m−1) and then adds a previous filter coefficient value C1(k) to the multiplication result μE(k)X(k−m−1).

The second through m-th coefficient generators 222 through 22m have the same elements as the first coefficient generator 221 and generate current filter coefficient values C2(k+1) through Cm(k+1), respectively, using the delayed input signals (X(k−m−2), . . . , and X(k−n)), respectively, in the same manner that the first coefficient generator 221 generates the current filter coefficient value C1(k+1).

The coefficient update circuit 200 generates each of the current filter coefficient values C1(k+1) through Cm(k+1) by performing two multiplication operations using the multiplier 210 and the multiplier of a corresponding coefficient generator. Because of the multiplication operations, the coefficient update circuit 200 does not operate at high speed. In other words, since the coefficient update circuit 200 should perform two multiplication operations to generate each of the current filter coefficient values C1(k+1) through Cm(k+1), the entire operation cycle of the conventional coefficient update circuit 200 lengthens, and thus, the coefficient update circuit 200 may not be able to provide the coefficient multiplier circuit 120 with updated filter coefficients in time, thus lowering the stability of an entire update loop comprised of the coefficient multiplier circuit 120, the adder circuit 130, the error generation circuit 140, and the conventional coefficient update circuit 200. In addition, the coefficient update circuit 200 includes a plurality of multipliers and thus occupies a large area and consumes a considerable amount of power.

FIG. 3 is a circuit diagram of an example of the conventional coefficient update circuit 200 of FIG. 1 that uses a sign-sign LMS (SS LMS) algorithm. Referring to FIG. 3, the SS LMS algorithm used by the coefficient update circuit 200 can be expressed using Equation (2):
C(t+1)=C(t)+μsgn(E(t))sgn(X(t)) (2)

where C(t+1) is a current filter coefficient value, C(t) is a previous filter coefficient value, μ is an update size, E(t) is an error signal generated at a predetermined moment t of time, X(t) is a delayed input signal generated at the predetermined moment t of time, i.e., one of X(k−m−1), X(k−m−2), . . . , and X(k−n) of FIG. 1, and sgn is a function that outputs a value of +1 when the sign of the error signal E(t) or the delayed input signal X(t) has a positive value and outputs a value of −1 when the sign of the error signal E(t) or the delayed input signal X(t) has a negative value. Equation (2) can be simplified as Equation (3):
C(t+1)=C(t)±μ (3).

Referring to FIG. 3, the coefficient update circuit 200 includes a sign detector (SGN) 240 and a plurality of coefficient generators, i.e., first through m-th coefficient generators 251 through 25m.

The sign detector 240 detects the sign of the error signal E(k) and provides the detection result to the first through m-th coefficient generators 251 through 25m.

The first coefficient generator 251 includes a sign detector (SGN) 261, an exclusive OR (XOR) gate 262, an adder 263, a subtractor 264, a multiplexer (MUX) 265, and a delay element (D) 266. The first coefficient generator 251 performs an XOR operation on the detection result provided by the sign detector 240 and a result of detecting the sign of the delayed input signal X(k−m−1) obtained by the sign detector 261 and provides the XOR operation result to the multiplexer 265, thereby generating a current filter coefficient value C1(k+1).

The second through m-th coefficient generators 252 through 25m have the same elements as the first coefficient generator 251 and generate current filter coefficient values C2(k+1) through Cm(k+1), respectively, using the delayed input signals X(k−m−2) through X(k−n), respectively, in the same manner that the first coefficient generator 251 generates the current filter coefficient value C1(k+1).

The coefficient update circuit 200 of FIG. 3 includes the XOR gate 262 and the multiplexer 265 instead of multipliers. Thus, the coefficient update circuit 200 of FIG. 3 achieves higher coefficient updating speed and occupies a smaller area than the coefficient update circuit 200 of FIG. 2. However, the coefficient update circuit 200 of FIG. 3 provides only two update values, i.e., ±μ. Accordingly, the coefficient update circuit 200 of FIG. 3 cannot appropriately update filter coefficients especially when the levels of the delayed input signals and the error signal dramatically change, i.e., when channel characteristics dramatically change in accordance with the passage of time. Thus, the performance of the conventional adaptive equalizer 100 of FIG. 1 that includes the coefficient update circuit 200 of FIG. 3 can be adversely affected.

### SUMMARY OF THE INVENTION

The present invention provides a coefficient update circuit, which can achieve high coefficient updating speed and which can appropriately update filter coefficients even when the levels of delayed input signals and an error signal dramatically change.

The present invention also provides an adaptive equalizer having the coefficient update circuit.

The present invention also provides a coefficient update method of the adaptive equalizer.

According to an aspect of the present invention, there is provided a coefficient update circuit of an adaptive equalizer. The coefficient circuit includes: an error level detector, which detects a level of an error signal that is a difference between a level of an output signal of the adaptive equalizer and a desired signal level; and a plurality of coefficient generators, which generate current filter coefficient values by adding update values designated by the level of the error signal and the levels of delayed input signals to previous filter coefficient values, the delayed input signals being generated by delaying an input signal of the adaptive equalizer for a predetermined amount of time. The generated current filter coefficient values are provided to a filter included in the adaptive equalizer.

In one embodiment, the level of the error signal may be determined based on the sign and magnitude of the error signal, and the level of each of the delayed input signals may be determined based on the sign and magnitude of a corresponding delayed input signal.

In another embodiment, the number of levels that the error signal may be set to may be determined based on the size in bits of the error signal, and the number of levels that each of the delayed input signals may be set to may be determined based on the size in bits of a corresponding delayed input signal.

In another embodiment, each of the coefficient generators includes: an input level detector, which detects the level of a corresponding delayed input signal; an update value table, which stores the update values; an adder, which adds one of the update values to a corresponding previous filter coefficient value; and a delay element, which generates the corresponding previous filter coefficient value by delaying a corresponding current filter coefficient value.

In another embodiment, the update value table comprises a plurality of registers. In another embodiment, the delay element comprises a D flipflop.

According to another aspect of the present invention, there is provided an adaptive equalizer. The adaptive equalizer includes: a delay circuit, which generates a plurality of delayed input signals by delaying an input signal for a predetermined amount of time, the delayed input signals being divided into a group of first delayed input signals and a group of second delayed input signals; a coefficient multiplier circuit, which multiplies the first delayed input signals with respective filter coefficients and outputs the multiplication results; an adder circuit, which generates an output signal by adding the multiplication results; an error generation circuit, which generates an error signal that is a difference between the output signal and a desired signal level; and a coefficient update circuit, which detects a level of the error signal and levels of the second delayed input signals and generates current values of the filter coefficients by updating previous values of the filter coefficients based on update values designated by the detected level of the error signal and the detected levels of the second delayed input signals.

In one embodiment, the coefficient update circuit comprises: an error level detector, which detects the level of the error signal; and a plurality of coefficient generators, which generates the current filter coefficient values by adding update values designated by the detected level of the error signal and the detected levels of the second delayed input signals to the previous filter coefficient values.

In another embodiment, the level of the error signal is determined based on a sign and magnitude of the error signal, and the level of each of the second delayed input signals is determined based on a sign and magnitude of a corresponding delayed input signal.

In another embodiment, the number of levels that the error signal may be set to is determined based on a size in bits of the error signal, and the number of levels that each of the second delayed input signals may be set to is determined based on a size in bits of a corresponding delayed input signal.

In another embodiment, each of the coefficient generators comprises: an input level detector, which detects the level of a corresponding second delayed input signal; an update value table, which stores the update values; an adder, which adds one of the update values to a corresponding previous filter coefficient value; and a delay element, which generates the corresponding previous filter coefficient value by delaying a corresponding current filter coefficient value.

In another embodiment, the update value table comprises a plurality of registers. In another embodiment, the delay element comprises a D flipflop.

According to another aspect of the present invention, there is provided an adaptive equalizer. The adaptive equalizer includes: a filter, which multiplies a plurality of first delayed input signals with respective filter coefficients, outputs the multiplication results, and generates an output signal by adding the multiplication results, the first delayed input signals being generated by delaying an input signal for a predetermined amount of time; an error generation circuit, which generates an error signal that is a difference between the level of the output signal and a desired signal level; and a coefficient update circuit, which detects a level of the error signal and levels of a plurality of second delayed input signals and generates current values of the filter coefficients by updating previous values of the filter coefficients based on update values designated by the detected level of the error signal and the detected levels of the second delayed input signals, the second delayed input signals being generated by delaying the input signal for a predetermined amount of time.

According to another aspect of the present invention, there is provided a coefficient update method of an adaptive equalizer. The coefficient update method includes: detecting a level of an error signal that is a difference between a level of an output signal of the adaptive equalizer and a desired signal level; detecting levels of a plurality of delayed input signals generated by delaying an input signal of the adaptive equalizer for a predetermined amount of time; selecting update values from an update value table with reference to the detected level of the error signal and the detected levels of the delayed input signals; and adding the selected update values to previous values of filter coefficients and outputting the addition results as current values of the filter coefficients. The current filter coefficient values are provided to a filter included in the adaptive equalizer.

In one embodiment, the level of the error signal is determined based on a sign and magnitude of the error signal, and the level of each of the delayed input signals is determined based on a sign and magnitude of a corresponding delayed input signal.

In another embodiment, the number of levels that the error signal may be set to is determined based on a size in bits of the error signal, and the number of levels that each of the delayed input signals may be set to is determined based on a size in bits of a corresponding delayed input signal.

The coefficient update circuit and method of an adaptive equalizer according to the present invention can improve coefficient update speed and can appropriately update filter coefficients even when the levels of delayed input signals and an error signal dramatically change. In addition, the adaptive equalizer according to the present invention can achieve high channel equalization performance.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional adaptive equalizer having a conventional coefficient update circuit that uses a least mean square (LMS) algorithm;

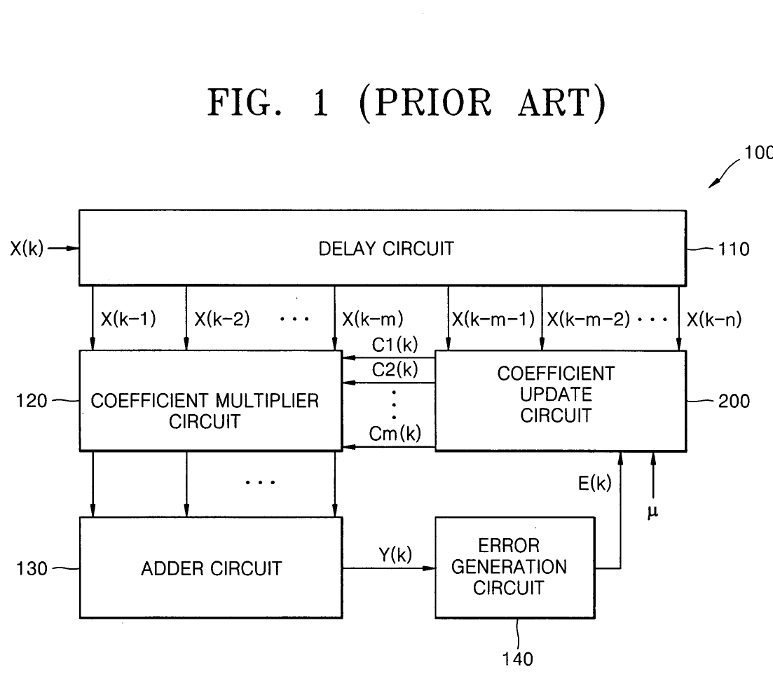

FIG. 2 is a circuit diagram of an example of the conventional coefficient update circuit of FIG. 1;

FIG. 3 is a circuit diagram of an example of the conventional coefficient update circuit of FIG. 1 that uses a sign-sign LMS algorithm;

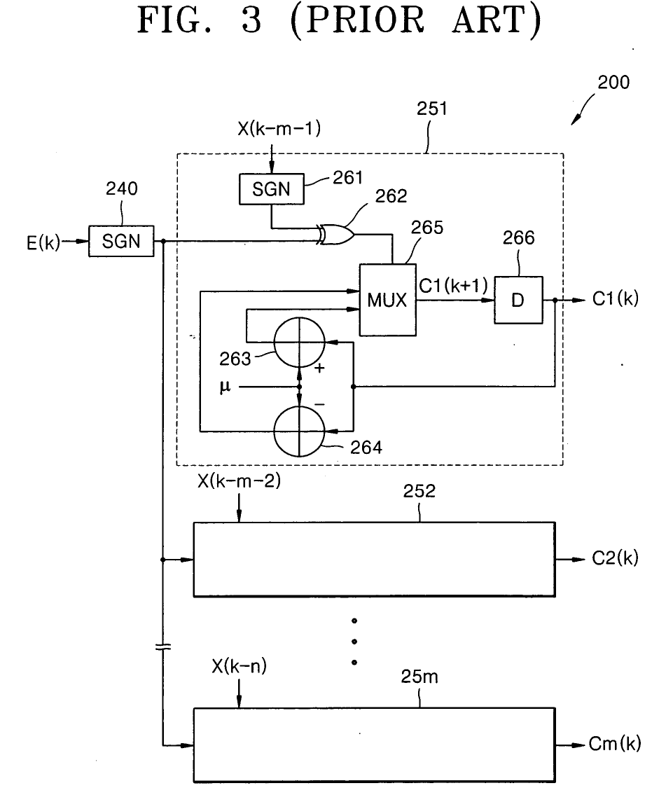

FIG. 4 is a block diagram of an adaptive equalizer including a coefficient update circuit according to an exemplary embodiment of the present invention that uses a level detection LMS (LD LMS) algorithm;

FIG. 5 is a circuit diagram of the coefficient update circuit of FIG. 4; and

FIG. 6 is a flowchart of a coefficient update method according to an exemplary embodiment of the present invention.

### DETAILED DESCRIPTION OF THE INVENTION

The present invention will now be described more fully with reference to the accompanying drawings in which exemplary embodiments of the invention are shown. In the drawings, like reference numerals represent like elements.

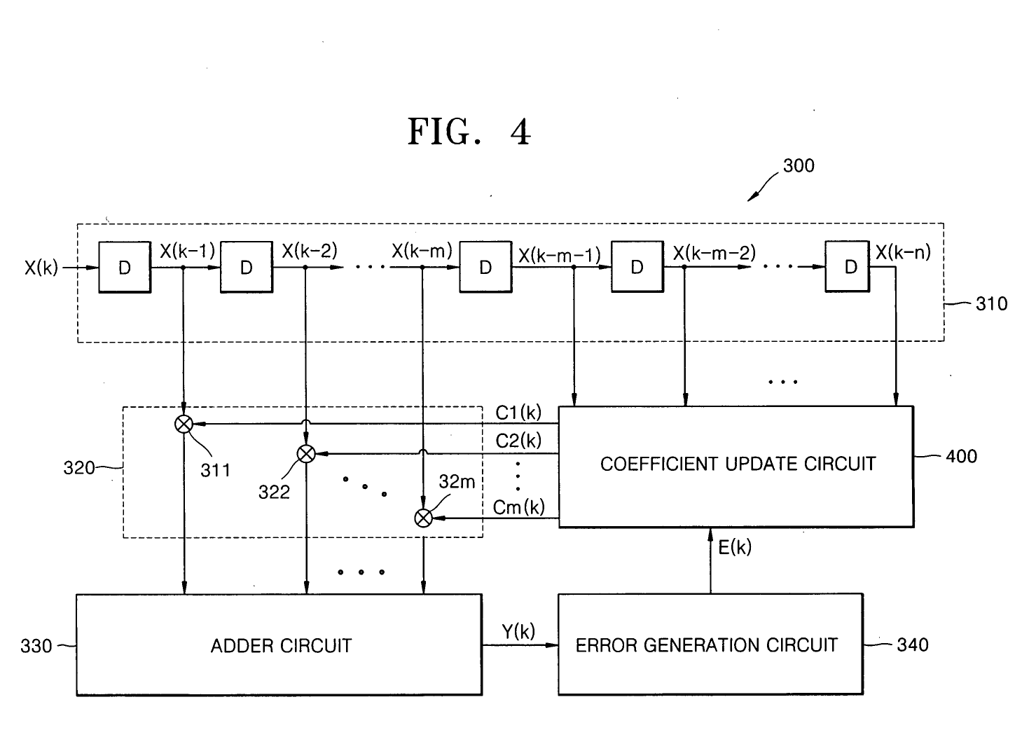

FIG. 4 is a block diagram of an adaptive equalizer 300 including a coefficient update circuit 400 according to an exemplary embodiment of the present invention that uses a level detection least mean square (LD LMS) algorithm. Referring to FIG. 4, the adaptive equalizer 300 includes a delay circuit 310, a coefficient multiplier circuit 320, an adder circuit 330, an error generation unit 340, and the coefficient update circuit 400. In exemplary applications, the adaptive equalizer 300 of the present invention may be applied to an optical disc player having optical channels or a hard disc drive having magnetic channels.

The delay circuit 310, the coefficient multiplier circuit 320, and the adder circuit 330 constitute a finite impulse response (FIR) filter having m taps. The FIR filter compensates for distortion of an input signal X(k) transmitted thereto via a channel based on filter coefficients C1(k) through Cm(k) output from the coefficient update circuit 400 and outputs an output signal Y(k) having a desired signal level as the compensation result.

The delay circuit 310 includes a plurality of delay elements (D) connected to one another in series. Each of the delay elements D includes a D flipflop, which delays the input signal X(k) for a predetermined amount of time, for example, for one cycle of a clock signal, in response to the clock signal.

The delay circuit 310 generates a plurality of delayed input signals, i.e., first through n-th delayed input signals X(k−1), . . . , X(k−m), . . . , X(k−n), by delaying the input signal X(k) for a predetermined amount of time, for example, for a multiple of the cycle of the clock signal. Here, m is a natural number greater than 1, and n is a natural number larger than m and satisfies the following equation: n=2m. For example, the input signal X(k) may be a 6-bit digital radio frequency (RF) signal output from an analog-to-digital converter (ADC) of a system for reproducing data from an optical disc. The RF signal is a signal read out from a compact disc (CD) or a digital versatile disc (DVD).

The coefficient multiplication signal 320 includes a plurality of multipliers, i.e., first through m-th multipliers 321 through 32m. The coefficient multiplier circuit 320 multiplies first signals of delayed input signals X(k−1) through X(k−m) with respective filter coefficients C1(k) through Cm(k) output from the coefficient update circuit 400 and outputs the multiplication results to the adder circuit 330.

The adder circuit 330 adds up the multiplication results output from the coefficient multiplier circuit 320, thereby generating the output signal Y(k). For example, the output signal Y(k) may be a 6-bit digital signal input to a viterbi decoder included in the system for reproducing data from the optical disc.

The error generation circuit 340 calculates a difference between the level of the output signal Y(k) and a desired signal level (for example, an input signal level required by the viterbi decoder) and outputs an error signal E(k) as the calculation result. For example, the error signal E(k) may be a 6-bit digital signal.

The coefficient update circuit 400 utilizes an LD LMS algorithm. The LD LMS algorithm detects the levels of the error signal E(k) and second signals of the delayed input signals X(k−m−1) through X(k−n) and updates previous filter coefficient values as current filter coefficient values using updated values that are determined based on the detection results. The updated values are stored in an update value table included in the coefficient update circuit 400. The size of the update value table or the number of update values stored in the update value table is determined based on a total number of values that the level of the error signal E(k) may be set to and a total number of levels that the level of one of the delayed input signals, for example, the level of the delayed input signal X(k−m−1), may be set to.

The level of the error signal E(k) is determined based on the sign and size, or magnitude, of the error signal E(k). The sign of the error signal E(k) is designated by a most significant bit of a plurality of bits of the error signal E(k), and the size of the error signal E(k) is designated by the remainder of the bits-of the error signal E(k). Likewise, the level of one of the delayed input signals X(k−m−1) through X(k−n) is determined based on the sign and size of the corresponding delayed input signal. The sign of the corresponding delayed input signal is designated by a most significant bit of a plurality of bits of the corresponding delayed input signal, and the size of the (m+1)-th delayed input signal is designated by the remainder of the bits of the corresponding delayed input signal.

The number of values that the level of the error signal E(k) may be set to is determined based on the size in bits of the error signal E(k) or based on the resolution of the error signal E(k), and the number of values that the level of the corresponding delayed input signal may be set to is determined based on the size in bits of the corresponding delayed input signal. For example, if the input signal X(k) is a 6-bit digital signal, the number of levels of the error signal E(k) and the number of levels of the corresponding delayed input signal may be set to 8.

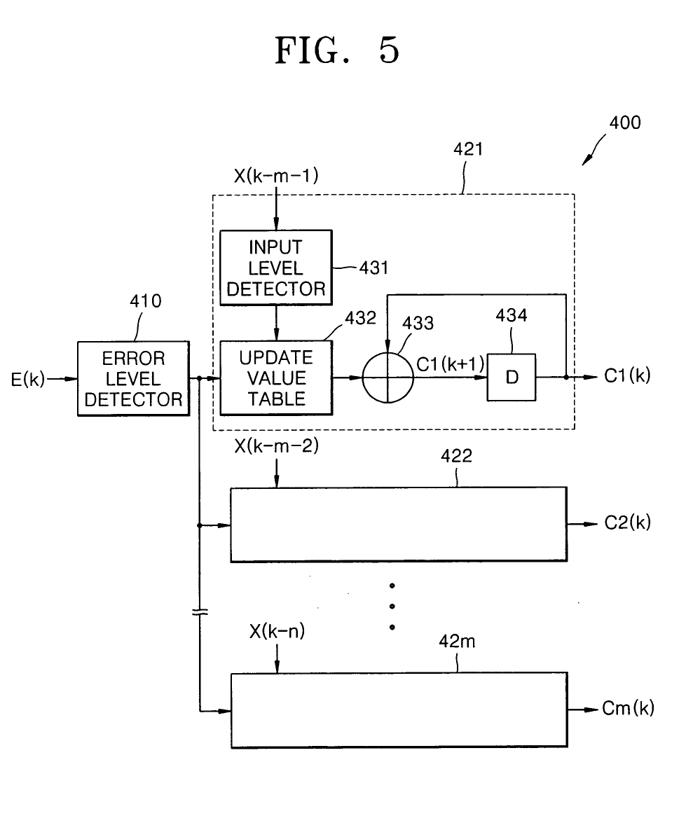

FIG. 5 is a circuit diagram of the coefficient update circuit 400 of FIG. 4. Referring to FIG. 5, the coefficient update circuit 400 includes an error level detector 410 and a plurality of coefficient generators, i.e., first through m-th coefficient generators 421 through 42m.

The error level detector 410 detects the level of the error signal E(k) based on a bit value of the error signal E(k) at a predetermined moment k of time. The number of levels that the error signal E(k) may be set to is determined based on the size in bits of the error signal E(k). For example, as the size in bits of the error signal E(k) increases, the number of levels that the error signal E(k) may be set to increases. The detected level of the error signal E(k) is provided to the coefficient generators 421 through 42m.

The first coefficient generator 421 includes an input level detector 431, an update value table 432, an adder 433, and a delay element (D) 434. The first coefficient generator 421 adds a previous filter coefficient value C1(k) to an update value determined based on the detected level of the error signal E(k) and a detected level of the (m+1)-th delayed input signal X(k−m−1), thereby updating the previous filter coefficient value C1(k) into the current filter coefficient value C1(k+1).

The input level detector 431 detects the level of the (m+1)-th delayed input signal X(k−m−1) based on a bit value of the (m+1)-th delayed input signal X(k−m−1). The number of levels that the delayed input signal may be set to is determined based on the size in bits of the (m+1)-th delayed input signal X(k−m−1).

The update value table 432 includes a plurality of registers (not shown) and stores update values corresponding to the detected level of the error signal E(k) and the detected level of the (m+1)-th delayed input signal X(k−m−1). For example, if the number of levels of the error signal E(k) and the number of levels of the (m+1)-th delayed input signal X(k−m−1) are set to 8, then 0, ±μ, ±2μ, . . . , and ±7μ (where μ is an update size) may be stored in the update value table 432 as update values. The update size μ is a step size or an adaptation constant used for controlling the convergence rates of filter coefficients. The update value table 432 outputs one of the update values stored therein corresponding to the detected level of the error signal E(k) and the detected level of the (m+1)-th delayed input signal.

The adder 433 adds the update value output from the update value table 432 to the previous filter coefficient value C1(k), thereby generating the current filter coefficient value C1(k+1).

The delay element 434 delays the current filter coefficient value C1(k+1), thereby generating the previous filter coefficient value C1(k). The delay element 434 includes a D flipflop, which operates in response to a predetermined clock signal.

The second through m-th coefficient generators 422 through 42m include the same elements as the first coefficient generator 421 and generate the respective current filter coefficient values C2(k+1) through Cm(k+1) using the respective delayed input signals X(k−m−2) through X(k−n) in the same manner that the first coefficient generator generates the current filter coefficient value C1(k+1).

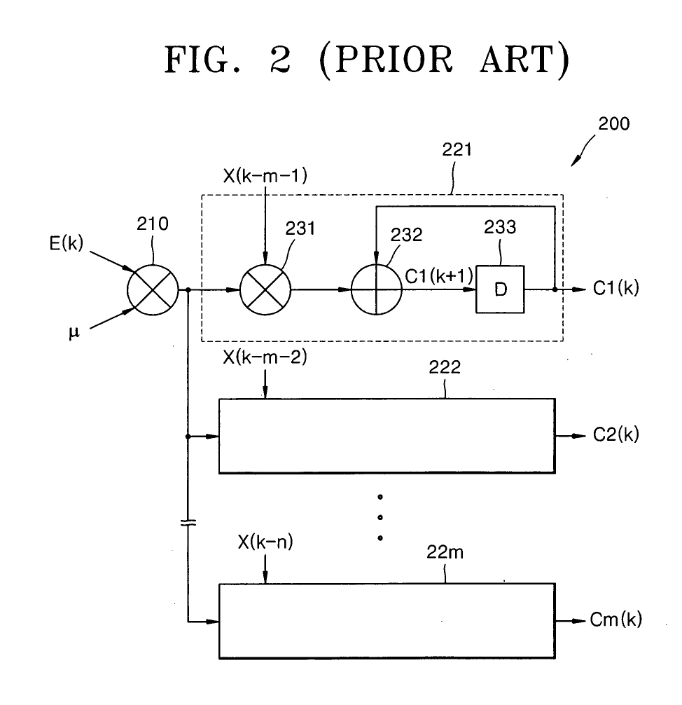

The coefficient update circuit 400 updates filter coefficients using a plurality of level detectors (410 and 431) and the update value table 432 while the conventional coefficient update circuit 200 of FIG. 2 update filter coefficients using a plurality of multipliers. Thus, the coefficient update circuit 400 can improve coefficient update speed, occupies a smaller area, and consumes less power than the conventional coefficient update circuit 200 of FIG. 2. In addition, since the coefficient update circuit 400 updates filter coefficients using a plurality of update values, it can appropriately update the filter coefficients even when the levels of delayed input signals and an error signal dramatically change. The channel equalization performance of the adaptive equalizer 300 including the coefficient update circuit 400 is thus improved.

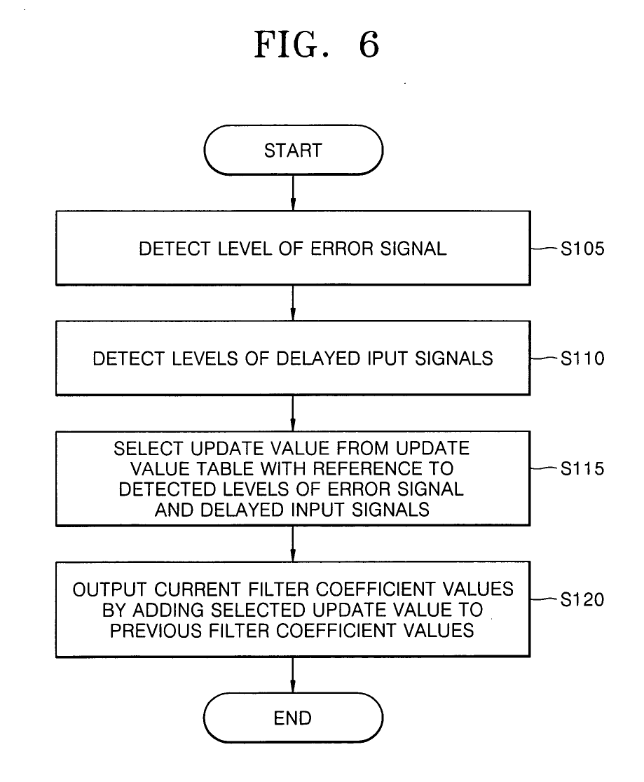

FIG. 6 is a flowchart of a coefficient update method according to an exemplary embodiment of the present invention. The coefficient update method is applicable to the coefficient update circuit 400 of FIG. 5.

The coefficient update method will now be described in detail with reference to FIGS. 4, 5, and 6.

Referring to FIG. 6, in operation S105, the error level detector 410 detects the level of the error signal E(k), which is a difference between the level of the output signal Y(k) of the adaptive equalizer 300 and the desired signal level. The level of the error signal E(k) is determined based on a bit value of the error signal E(k), i.e., the sign and size of the error signal E(k), and the number of levels that the error signal E(k) may be set to is determined based on the size in bits of the error signal E(k).

In operation S110, the input level detectors 431 included in the first through m-th coefficient generators 421 through 42m detect the levels of the (m+1)-th through n-th delayed input signals X(k−m−1) through X(k−n), which are obtained by delaying the input signal X(k) of the adaptive equalizer 300 for a predetermined amount of time. The levels of the (m+1)-th through n-th delayed input signals X(k−m−1) through X(k−n) are determined based on the respective bit values, i.e., the respective signs and sizes, and the number of levels that the (m+1)-th through n-th delayed input signals X(k−m−1) through X(k−n) may be set to are determined based on the respective sizes in bits.

In operation S115, update values are selected from the update value table 432 with reference to the detected level of the error signal E(k) and the detected levels of the (m+1)-th through n-th delayed input signals.

In operation S120, current filter coefficient values are generated by adding the update values selected in operation S115 to the respective previous filter coefficient values and are then output. The output current filter coefficient values are provided to a filter included in the adaptive equalizer 300.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A coefficient update circuit of an adaptive equalizer, comprising:
an error level detector, which detects a level of an error signal that is a difference between a level of an output signal of the adaptive equalizer and a desired signal level; and
a plurality of coefficient generators, which generate current filter coefficient values by adding update values designated by the level of the error signal and the levels of delayed input signals to previous filter coefficient values, the delayed input signals being generated by delaying an input signal of the adaptive equalizer for a predetermined amount of time,
wherein the generated current filter coefficient values are provided to a filter included in the adaptive equalizer.

2. The coefficient update circuit of claim 1, wherein the level of the error signal is determined based on a sign and magnitude of the error signal, and the level of each of the delayed input signals is determined based on a sign and magnitude of a corresponding delayed input signal.

3. The coefficient update circuit of claim 2, wherein the number of levels that the error signal may be set to is determined based on a size in bits of the error signal, and the number of levels that each of the delayed input signals may be set to is determined based on a size in bits of a corresponding delayed input signal.

4. The coefficient update circuit of claim 3, wherein each of the coefficient generators comprises:
an input level detector, which detects the level of a corresponding delayed input signal;
an update value table, which stores the update values;
an adder, which adds one of the update values to a corresponding previous filter coefficient value; and
a delay element, which generates the corresponding previous filter coefficient value by delaying a corresponding current filter coefficient value.

5. The coefficient update circuit of claim 4, wherein the update value table comprises a plurality of registers.

6. The coefficient update circuit of claim 4, wherein the delay element comprises a D flipflop.

7. An adaptive equalizer comprising:
a delay circuit, which generates a plurality of delayed input signals by delaying an input signal for a predetermined amount of time, the delayed input signals being divided into a group of first delayed input signals and a group of second delayed input signals;
a coefficient multiplier circuit, which multiplies the first delayed input signals with respective filter coefficients and outputs the multiplication results;
an adder circuit, which generates an output signal by adding the multiplication results;
an error generation circuit, which generates an error signal that is a difference between the output signal and a desired signal level; and
a coefficient update circuit, which detects a level of the error signal and levels of the second delayed input signals and generates current values of the filter coefficients by updating previous values of the filter coefficients based on update values designated by the detected level of the error signal and the detected levels of the second delayed input signals.

8. The adaptive equalizer of claim 7, wherein the coefficient update circuit comprises:
an error level detector, which detects the level of the error signal; and
a plurality of coefficient generators, which generates the current filter coefficient values by adding update values designated by the detected level of the error signal and the detected levels of the second delayed input signals to the previous filter coefficient values.

9. The adaptive equalizer of claim 8, wherein the level of the error signal is determined based on a sign and magnitude of the error signal, and the level of each of the second delayed input signals is determined based on a sign and magnitude of a corresponding delayed input signal.

10. The adaptive equalizer of claim 9, wherein the number of levels that the error signal may be set to is determined based on a size in bits of the error signal, and the number of levels that each of the second delayed input signals may be set to is determined based on a size in bits of a corresponding delayed input signal.

11. The adaptive equalizer of claim 10, wherein each of the coefficient generators comprises:
an input level detector, which detects the level of a corresponding second delayed input signal;
an update value table, which stores the update values;
an adder, which adds one of the update values to a corresponding previous filter coefficient value; and
a delay element, which generates the corresponding previous filter coefficient value by delaying a corresponding current filter coefficient value.

12. The adaptive equalizer of claim 11, wherein the update value table comprises a plurality of registers.

13. The adaptive equalizer of claim 11, wherein the delay element comprises a D flipflop.

14. An adaptive equalizer comprising:
a filter, which multiplies a plurality of first delayed input signals with respective filter coefficients, outputs the multiplication results, and generates an output signal by adding the multiplication results, the first delayed input signals being generated by delaying an input signal for a predetermined amount of time;
an error generation circuit, which generates an error signal that is a difference between the level of the output signal and a desired signal level; and
a coefficient update circuit, which detects a level of the error signal and levels of a plurality of second delayed input signals and generates current values of the filter coefficients by updating previous values of the filter coefficients based on update values designated by the detected level of the error signal and the detected levels of the second delayed input signals, the second delayed input signals being generated by delaying the input signal for a predetermined amount of time.

15. A coefficient update method of an adaptive equalizer, comprising
detecting a level of an error signal that is a difference between a level of an output signal of the adaptive equalizer and a desired signal level; and
detecting levels of a plurality of delayed input signals generated by delaying an input signal of the adaptive equalizer for a predetermined amount of time;
selecting update values from an update value table with reference to the detected level of the error signal and the detected levels of the delayed input signals; and
adding the selected update values to previous values of filter coefficients and outputting the addition results as current values of the filter coefficients,
wherein the current filter coefficient values are provided to a filter included in the adaptive equalizer.

16. The coefficient update method of claim 15, wherein the level of the error signal is determined based on a sign and magnitude of the error signal, and the level of each of the delayed input signals is determined based on a sign and magnitude of a corresponding delayed input signal.

17. The coefficient update method of claim 16, wherein the number of levels that the error signal may be set to is determined based on a size in bits of the error signal, and the number of levels that each of the delayed input signals may be set to is determined based on a size in bits of a corresponding delayed input signal.
